(19) United States
(12) Patent Application Publication
(10) Pub. No.: US 2008/0296566 A1
(43) Pub. Date: Dec. 4, 2008

(54) Making organic thin film transistor substrates for display devices

(75) Inventors: Keun-Kyu Song, Yongin-si (KR); Jung-Han Shin, Yongin-si (KR); Bo-Sung Kim, Seoul (KR); Seon-Pil Jang, Seoul (KR); Seung-Hwan Cho, Hwaseong-si (KR); Min-Ho Yoon, Suwon-si (KR); Jung-Hun Noh, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 12/156,213

(22) Filed: May 30, 2008

(30) Foreign Application Priority Data
Jun. 1, 2007 (KR) 10-2007-0053772

(51) Int. Cl. H01L 29/02; H01L 21/00; H01L 27/28

(52) U.S. Cl. 257/40; 438/99; 257/E29.002

(57) ABSTRACT

An organic thin film transistor substrate for a display device includes a gate line, a data line insulated from the gate line, at least two organic thin film transistors, each of which is connected between the gate line and the data line, and both of which are commonly connected to a main drain electrode, and a pixel electrode connected to the main drain electrode.

### RELATED APPLICATIONS

This application claims priority and is an accurate translation of Korean Patent Application No. 10-2007-0053772, filed Jun. 1, 2007, the entire disclosure of which is incorporated herein by reference.

### BACKGROUND

1. Technical Field

This invention relates to organic thin film transistor substrates for display devices.

2. Related Art

Display devices include electro optic display, such as liquid crystal display (“LCD”), electrophoretic display, electrowetting display. The LCDs may be further classified into transmission type and reflection type displays.

Transmission-type display devices display images by projecting light generated by a backlight mounted on a rear portion of a display panel through the display panel and adjusting the amount of light transmitted therethrough by controlling the arrangement of the molecules of a liquid crystal layer disposed in the panel.

A reflection-type display displays an image by selectively transmitting externally supplied light to the liquid crystal panel therein through a switching function of the liquid crystal panel and then reflecting the transmitted light back through a front surface of the device using a reflection plate.

Both transmission- and reflection-type display panels typically use thin film transistors (“TFTs”) as the switching elements thereof. These generally include an amorphous silicon semiconductor or polycrystalline silicon semiconductor, a silicon oxide insulating layer, and a metal electrode. As new organic materials are developed, efforts are underway all over the world to employ organic semiconductors for making organic TFTs.

Inkjet printing methods are generally used to form organic TFTs. However, inkjet printing methods may cause a deterioration of the organic TFTs due to a malfunction or unstable operation of nozzles used in the inkjet printing method, which in turn, may result in a difficulty in implementing pixels in a normal manner. Additionally, conventional organic TFTs have another problem, in that they have a lower on-current than those of conventional TFTs.

### BRIEF SUMMARY

In accordance with the exemplary embodiments disclosed herein, organic thin film transistor substrates for display devices are provided, together with novel methods for manufacturing them, which are capable of preventing the problems caused by inkjet printing errors occurring during the formation of the organic thin film transistors thereof, as well as improving the above on-current problem of the organic thin film transistors by the provision of at least two organic thin film transistors in the place of one.

In one exemplary embodiment, an organic thin film transistor substrate for a display device comprises: A gate line; a data line insulated from the gate line; at least two organic thin film transistors, each of which is connected between the gate line and the data line, the organic thin film transistors being commonly connected to a main drain electrode; and, a pixel electrode connected to the main drain electrode.

The organic thin film transistors may be connected in parallel with one another.

The exemplary substrate may further include a storage pattern, comprising a storage lower electrode formed in the same plane as the gate line, and a storage upper electrode formed in the same plane as the data line.

The storage upper electrode may be connected to the main drain electrode.

The exemplary substrate may further comprise an auxiliary data line formed on the same plane as the data line and connected to any one of the organic thin film transistors.

The exemplary substrate may further comprise a data pad connected to the data line and the auxiliary data line.

The exemplary substrate may further comprise a connection line formed between the data line and the auxiliary data line.

Any one of the organic thin film transistors may comprise a first gate electrode connected to the gate line, a first source electrode connected to the data line, and a first organic semiconductor layer connected to the first source electrode and the main drain electrode.

Another one of the organic thin film transistors may comprise a second gate electrode connected to the gate line, a second source electrode connected to the auxiliary data line, and a second organic semiconductor layer connected to the second source electrode and the main drain electrode.

The exemplary substrate may further comprise a bank insulating layer having a hole exposing the first and second source electrodes and the main drain electrode.

The first gate electrode and the second gate electrode may be connected in parallel with each other.

The exemplary substrate may further comprise a storage pattern formed in the same plane as and parallel with the gate line.

The exemplary substrate may further include a storage pattern, comprising a storage lower electrode formed in the same plane and parallel with the gate line, and a storage upper electrode formed in the same plane as the data line and parallel with the gate line.

In another exemplary embodiment, a method for manufacturing an organic thin film transistor for a display device comprises: Forming a gate metal pattern on a substrate, the pattern including a gate line and a gate electrode; forming a gate insulating layer on the substrate and the gate metal pattern; forming a data metal pattern on the gate insulating layer, the pattern including a data line, at least two source electrodes, and a main drain electrode; and forming at least two organic semiconductor layers between the source electrodes and the main drain electrode using respectively different inkjet nozzles.

The forming of the data metal pattern may comprise forming a connection line and an auxiliary data line on the gate insulating layer, the connection line and the auxiliary data line being connected to the data line.

The forming of the gate metal pattern may comprise forming a storage pattern on the substrate so as to be parallel with the gate line.

The forming of the gate metal pattern may comprise forming a storage lower electrode on the substrate, and forming the data metal pattern may comprise forming a storage upper electrode on the gate insulating layer.

The method further comprising forming a bank insulating layer on the data line, the two source electrodes, and the main drain electrode, the bank insulating layer including holes to expose the main drain electrode and the two source electrodes.

The bank insulating layer may be formed of a photosensitive organic insulating material or a non-photosensitive organic insulating material.

A better understanding of the above and many other features and advantages of the organic thin film transistor substrates and methods for making them disclosed herein may be obtained from a consideration of the detailed description thereof below, particularly if such consideration is made in conjunction with the several views of the appended drawings, wherein like elements are referred to by like reference numerals throughout.

### BRIEF DESCRIPTION OF THE DRAWINGS

FIG. 1 is a partial top plan view of a first exemplary embodiment of an organic TFT substrate for a display device in accordance with the present invention, showing a single, exemplary pixel area thereof;

FIG. 2 is a partial cross sectional view of the first exemplary substrate of FIG. 1, as seen along the lines of the section I-I′ taken therein;

FIG. 3 is a partial top plan view of a second exemplary embodiment of an organic TFT substrate for a display device in accordance with the present invention, showing a single, exemplary pixel area thereof;

FIG. 4 is a partial top plan view of a third exemplary embodiment of an organic TFT substrate for a display device in accordance with the present invention, showing a single, exemplary pixel area thereof;

FIG. 5 is a partial cross sectional view of the third exemplary substrate of FIG. 4, as seen along the lines of the section II-II′ taken therein;

FIG. 6 is a partial top plan view of a fourth exemplary embodiment of an organic TFT substrate for a display device in accordance with the present invention, showing a single, exemplary pixel area thereof;

FIG. 7A is a partial cross sectional view of the fourth exemplary substrate of FIG. 6, as seen along the lines of the section III-III′ taken therein;

FIG. 7B is a partial cross sectional view of the fourth exemplary substrate of FIG. 6, as seen along the lines of the section IV-IV′ taken therein;

FIG. 8A is a partial top plan view of the first exemplary substrate of FIG. 1, illustrating an exemplary embodiment of a method for forming a gate metal pattern thereof in accordance with the present invention;

FIG. 8B is a partial cross sectional view of the first exemplary substrate of FIG. 8A, as seen along the lines of the section I-I′ taken therein, and further illustrating the exemplary method for forming the gate metal pattern thereof;

FIG. 9 is a partial cross sectional view of the first exemplary substrate of FIG. 8A, as seen along the lines of the section I-I′ taken therein, and illustrating an exemplary embodiment of a method for forming a gate insulating layer thereof in accordance with the present invention;

FIG. 10A is a partial top plan view of the first exemplary substrate of FIG. 1, illustrating an exemplary embodiment of a method for forming a data metal pattern thereof in accordance with the present invention;

FIG. 10B is a partial cross sectional view of the first exemplary substrate of FIG. 10A, as seen along the lines of the section I-I′ taken therein, and further illustrating the exemplary method for forming the data metal pattern thereof;

FIG. 11A is a partial top plan view of the first exemplary substrate of FIG. 1, showing a bank insulating layer, first and second organic semiconductor layers, and a passivation layer thereof;

FIG. 11B is a partial cross sectional view of the first exemplary substrate of FIG. 11A, as seen along the lines of the section I-I′ taken therein, and further illustrating the bank insulating layer, first and second organic semiconductor layers, and the passivation layer thereof;

FIGS. 12A, 12B, 12C, and 12D are partial cross sectional views of the first exemplary substrate of FIG. 11A, as seen along the lines of the section I-I′ taken therein and illustrating sequential steps of a exemplary method for manufacturing the bank insulating layer, the first and second organic semiconductor layers, and the passivation layer shown in FIGS. 11A and 11B;

FIG. 13A is a partial top plan view of the first exemplary substrate of FIG. 1, illustrating an exemplary embodiment of a method for forming a pixel electrode thereof in accordance with the present invention; and,

FIG. 13B is a partial cross sectional view of the first exemplary substrate of FIG. 13B, as seen along lines of the section I-I′ taken therein and further illustrating the exemplary method for forming a pixel electrode thereof.

### DETAILED DESCRIPTION

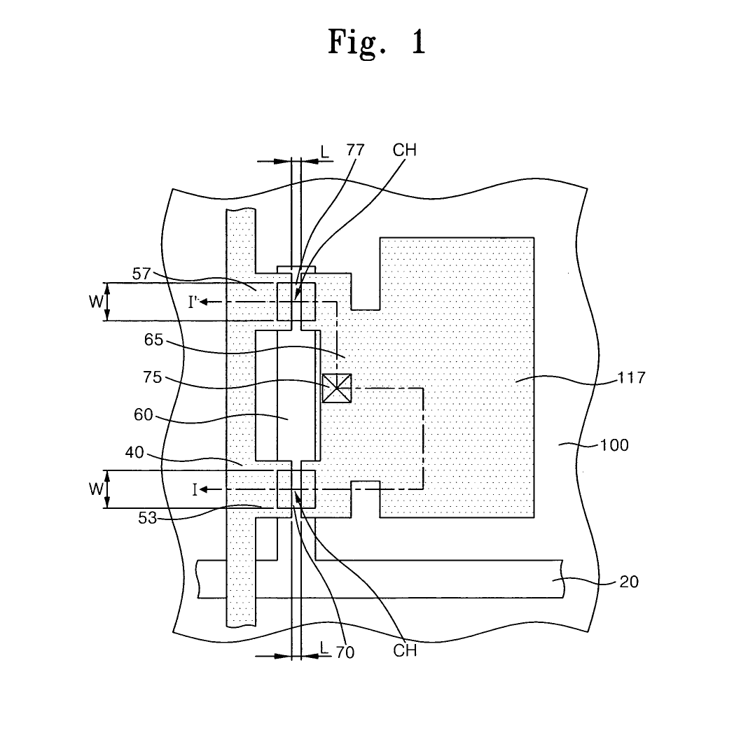

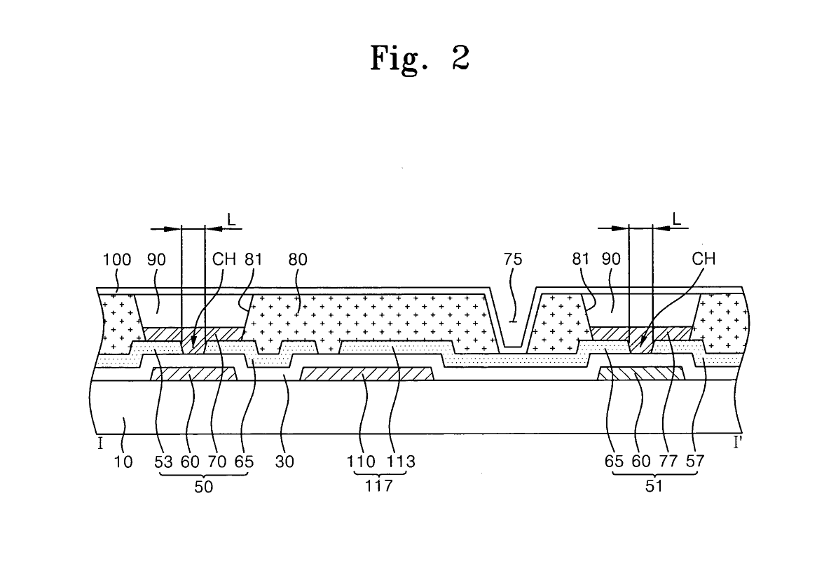

FIG. 1 is a partial top plan view of a first exemplary embodiment of an organic TFT substrate for a display device in accordance with the present invention, showing a single, exemplary pixel area thereof, and FIG. 2 is a partial cross sectional view of the first exemplary substrate of FIG. 1, as seen along the lines of the section I-I′ taken therein.

Referring to FIGS. 1 and 2, the organic TFT substrate includes a gate line 20, a data line 40, a gate insulating layer 30, first and second organic TFTs 50 and 51, a storage pattern 117, a bank insulating layer 80, an organic passivation layer 90, and a pixel electrode 100.

The gate line 20 receives a scan signal from a gate driver (not illustrated). The gate line 20 is formed on a substrate 10, which is made of glass or plastic, in a single layer or in stacked multiple layers using a metal material. The metal material may include any one of Mo, Nb, Cu, Al, Cr, Ag, W, and respective alloys thereof.

The data line 40 receives a pixel voltage signal from a data driver (not illustrated). The data line 40 crosses the gate line 20, and the gate insulating layer 30 is formed between the data line 40 and gate line 20. The data line 40 is formed in a single layer or in stacked multiple layers using a metal material.

The gate insulating layer 30 insulates a gate metal pattern including the gate line 20 and a data metal pattern including the data line 40.

The first and second organic TFTs 50 and 51 charge the pixel voltage signal from the data line 40 to the pixel electrode 100 in response to the scan signal of the gate line 20. The first and second organic TFTs 50 and 51 are connected in parallel with each other, and the width W and the length L of their effective channel CH is thereby increased to improve their effective on-current property. The first and second organic TFTs 50 and 51 include a main gate electrode 60, first and second source electrodes 53 and 57, a main drain electrode 65, and first and second organic semiconductor layers 70 and 77.

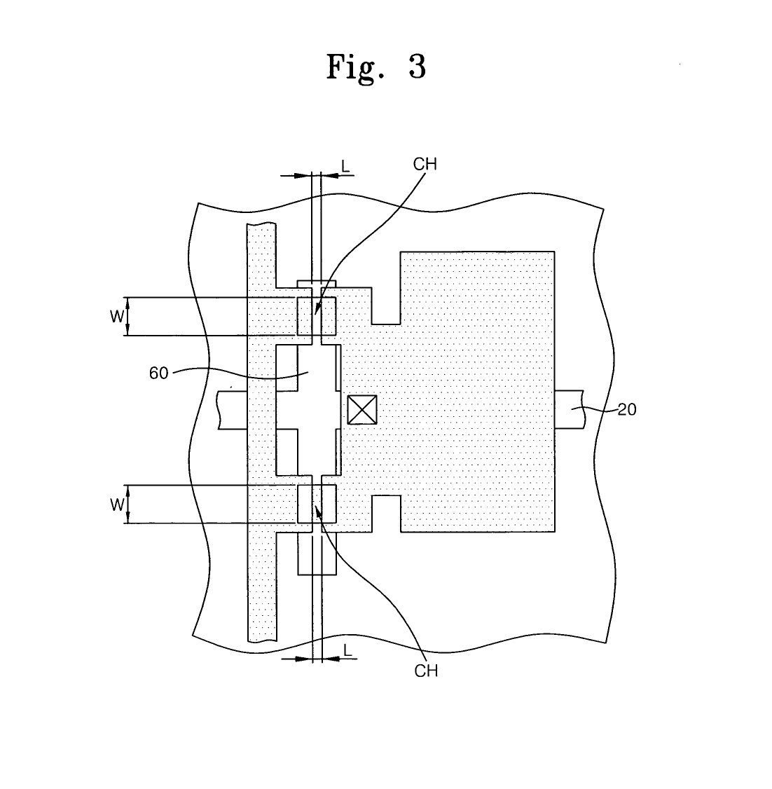

The main gate electrode 60 protrudes from the gate line 20, and may be formed so as to be parallel with the data line 40. As illustrated in the second exemplary embodiment of FIG. 3, a lower portion of the main gate electrode 60 may be connected to one organic TFT and an upper portion thereof may be connected to the other organic TFT with respect to the gate line 20. The main gate electrode 60 is commonly connected to the first and second organic TFTs 50 and 51. More specifically, the main gate electrode 60 is commonly connected to the first and second organic TFTs 50 and 51, and supplies the scan signal from the gate line 20 to the first and second organic TFTs 50 and 51. The main gate electrode 60 protrudes from the gate line 20, and may be formed of the same material as the gate line 20.

The first and second source electrodes 53 and 57 protrude from the data line 40, and supply the pixel voltage signal to the first and second organic TFTs 50 and 51, respectively.

The main drain electrode 65 is commonly connected to the first and second organic TFTs 50 and 51, and the first and second organic semiconductor layers 70 and 77 are formed between the main drain electrode 65 and the first source electrode 53, and between the main drain electrode 65 and the second source electrode 57, respectively. The main drain electrode 65 is connected to the pixel electrode 100 via a contact hole 75. The main drain electrode 65 supplies the pixel voltage signal from the first and second source electrodes 53 and 57 to the pixel electrode 100. Accordingly, although, for example, the first organic TFT 50 may break down, the second organic TFT 51 will still supply the pixel voltage signal to the pixel electrode 100, and therefore, it is still possible to implement the pixels in a normal manner.

The first and second organic semiconductor layers 70 and 77 are formed in a hole 81, which is prepared in the bank insulating layer 80 so as to overlap the main gate electrode 60, the first and second source electrodes 53 and 57, and the main drain electrode 65. Accordingly, although one of the first and second TFTs 50 and 51 may break down, the other TFT will operate normally because two organic semiconductor layers 70 and 77 are provided, and therefore, it is possible to implement the associated pixels normally.

The organic semiconductor layers 70 and 77 are ohmic-connected between the first source electrode 53 and the main drain electrode 65 and between the second source electrode 57 and the main drain electrode 65, respectively, through a self assembled monolayer (“SAM”) process. More specifically, the difference between the work function of the first organic semiconductor layer 70 and the work function of one of the first source electrode 53 and the main drain electrode 65, or the difference between the work function of the second organic semiconductor layer 77 and the work function of one of the second source electrodes 57 and the main drain electrode 65, are reduced through the SAM process. Accordingly, the contact resistance between the first organic semiconductor layer 70 and one of the first source electrode 53 and the main drain electrode 65, or the contact resistance between the second organic semiconductor layer 77 and one of the second source electrode 57 and the main drain electrode 65, are likewise reduced.

The storage pattern 117 includes a storage lower electrode 110 and a storage upper electrode 113. The storage lower electrode 110 is formed on the substrate 10 and of the same material as the gate line 20. The storage upper electrode 113 is formed of the same material as the data line 40 on the gate insulating layer 30, and may be connected to the main drain electrode 65. The storage lower electrode 110 and the storage upper electrode 113 overlap so as to form a capacitor. More specifically, the storage capacitor is formed by overlapping the storage lower electrode 110 and the storage upper layer 113, with the gate insulating layer 30 disposed therebetween.

The bank insulating layer 80 defines the hole 81. A portion of the first and second source electrodes 53 and 57, and a portion of the main drain electrode 65, which are respectively exposed by the hole 81, overlap the first and second organic semiconductor layers 70 and 77.

The organic passivation layer 90 serves to protect the first and second organic TFTs 50 and 51. The organic passivation layer 90 is formed in the hole 81 over the first and second organic semiconductor layers 70 and 77.

As illustrated in FIGS. 1 and 2, the pixel electrode 100 is formed on the bank insulating layer 80 and organic passivation layer 90. The pixel electrode 100 is connected to the main drain electrode 65 via a contact hole 75. Accordingly, the pixel electrode 100 receives the pixel voltage signal from the main drain electrode 65, and implements the pixels normally. The pixel electrode 100 is formed of a transparent conductive material or a reflective conductive material. The transparent conductive material may comprise an indium tin oxide (“ITO”), a tin oxide (“TO”), an indium zinc oxide (“IZO”), and an indium tin zinc oxide (“ITZO”).

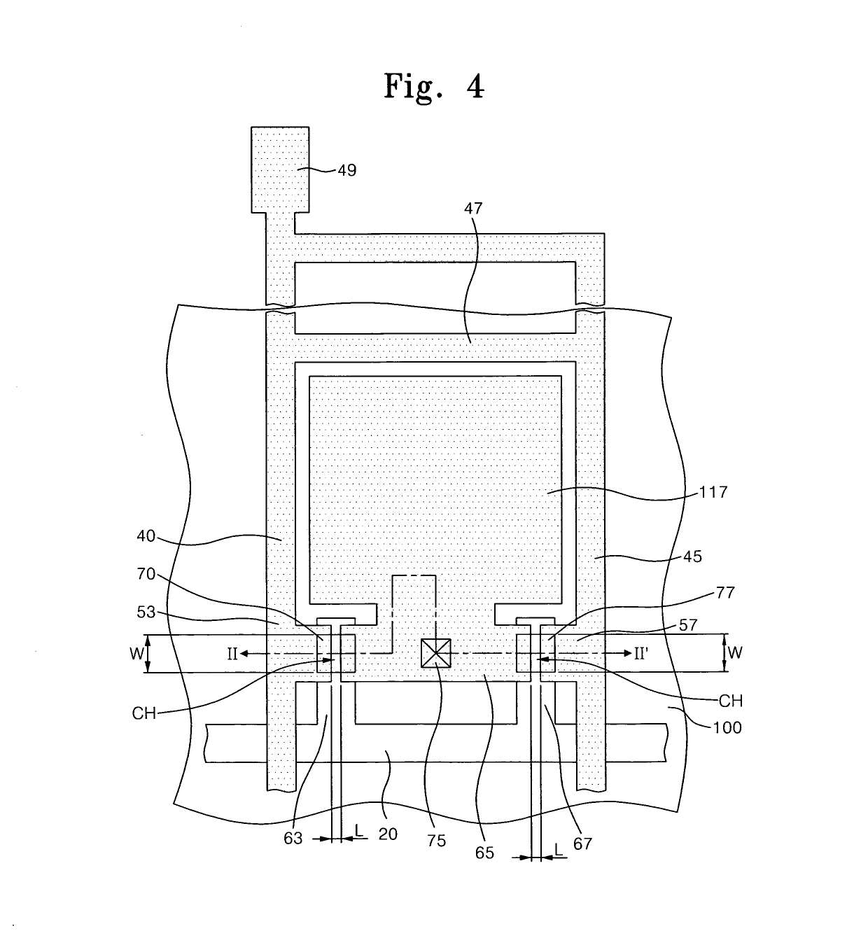

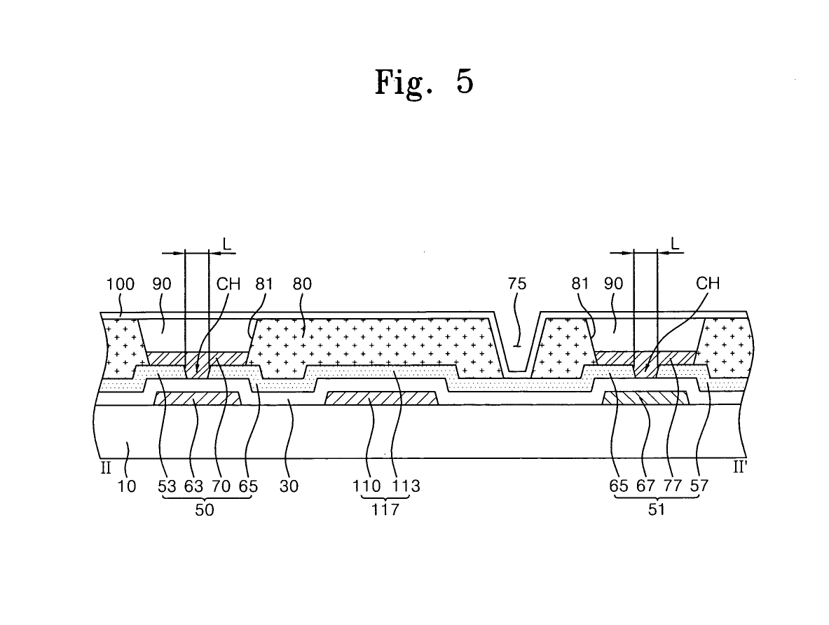

FIG. 4 is a partial top plan view of a third exemplary embodiment of an organic TFT substrate for a display device in accordance with the present invention, showing a single, exemplary pixel area thereof, and FIG. 5 is a partial cross sectional view of the third exemplary substrate of FIG. 4, as seen along the lines of the section II-II′ taken therein.

Referring to FIGS. 4 and 5, the organic TFT substrate includes a data pad 49, a gate line 20, a data line 40, an auxiliary data line 45, a connection line 47, a gate insulating layer 30, first and second organic TFTs 50 and 51, a storage pattern 117, a bank insulating layer 80, an organic passivation layer 90, and a pixel electrode 100.

The data pad 49 supplies the pixel voltage signal from a data driver (not illustrated) to the data line 40. The data pad 49 is formed in a non-display region of the substrate.

The gate line 20 is formed on the substrate 10 and receives a scan signal from a gate driver (not illustrated). The gate line 20 is formed with the same structure as that of the gate line of the first exemplary embodiment described above, and further detailed description thereof is therefore omitted for brevity.

The data line 40 is connected to the data pad 49 and receives the pixel voltage signal from the data pad 49. The data line 40 crosses the gate line 20. The data line 40 is formed with the same structure as that of the data line of the first exemplary embodiment described above, and further detailed description thereof is therefore omitted.

The auxiliary data line 45 is connected to the data pad 49 and arranged so as to be parallel with the data line 40. The auxiliary data line 45 is formed of the same material as the data line 40 on the gate insulating layer 30.

The connection line 47 is formed between the data line 40 and the auxiliary data line 45. The connection line 47 is connected between the data line 40 and the auxiliary data line 45. When the pixel voltage signal is supplied from the data pad 49 to the data line 40, the connection line 47supplies the auxiliary data line 45 with the pixel voltage signal that is equal to that on the data line 40. Thus, in the event the data line 40 should experience a break, the connection line 47 still supplies the pixel voltage signal to the organic TFTs through the auxiliary data line 45, thereby making it possible to prevent a line defect.

The gate insulating layer 30 insulates a gate metal pattern including the gate line 20 and a data metal pattern including the data line 40, auxiliary data line 45, and connection line 47.

The first organic TFT 50 includes a first gate electrode 63, a first source electrode 53, a main drain electrode 65, and a first organic semiconductor layer 70. The first gate electrode 63 protrudes from the gate line 20, and the first source electrode 53 protrudes from the data line 40. The first source electrode 53 supplies the pixel voltage signal from the data pad 49 to the main drain electrode 65. The main drain electrode 65, which faces the first source electrode 53, is connected to the pixel electrode 100 via a contact hole 75. The first organic semiconductor layer 70 is connected to the first source electrode 53 and the main drain electrode 65.

The second organic TFT 51 includes a second gate electrode 67, a second source electrode 57, a main drain electrode 65, and a second organic semiconductor layer 77. The second gate electrode 67 is connected to the gate line 20, and the second source electrode 57 protrudes from the auxiliary data line 45. The second source electrode 57 receives the pixel voltage signal, which is equal to that of the first source electrode 53, from the data pad 49. The main drain electrode 65 is commonly connected to the second organic TFT 51, and connected to the pixel electrode 100 via the contact hole 75. The main drain electrode 65 supplies the pixel voltage signal from the second source electrode 57 to the pixel electrode 100. The second organic semiconductor layer 77 is connected to the second source electrode 57 and the main drain electrode 65.

The storage pattern 117 includes a storage lower electrode 110 and a storage upper electrode 113. The storage lower electrode 110 is formed of the same material as the gate line 20, and the storage upper electrode 113 is formed of the same material as the data line 40. The storage lower electrode 110 and the storage upper electrode 113 are overlapped, with the gate insulating layer 30 disposed therebetween, so as to form a storage capacitor.

The bank insulating layer 80 defines a hole 81 that exposes a portion of the first and second source electrodes 53 and 57 and a portion of the main drain electrode 65.

The organic passivation layer 90, which is formed in the hole 81 over the first and second source electrodes 53 and 57 and the main drain electrode 65, serves to protect the first and second organic semiconductors 50 and 51.

As illustrated in FIG. 5, the pixel electrode 100 is formed of a transparent conductive material or a reflective conductive material on the organic passivation layer 90 and the bank insulating layer 80. The pixel electrode 100 is connected to the main drain electrode 65 of the first and second organic TFTs 50 and 51 via a contact hole 75. The pixel electrode 100 implements a pixel using the pixel voltage signal supplied from the main drain electrode 65.

Two organic TFTs have been used in the first to third exemplary embodiments of the present invention but the number of the organic TFTs is not limited thereto, and more than two organic TFTs may be employed in other possible embodiments of the present invention.

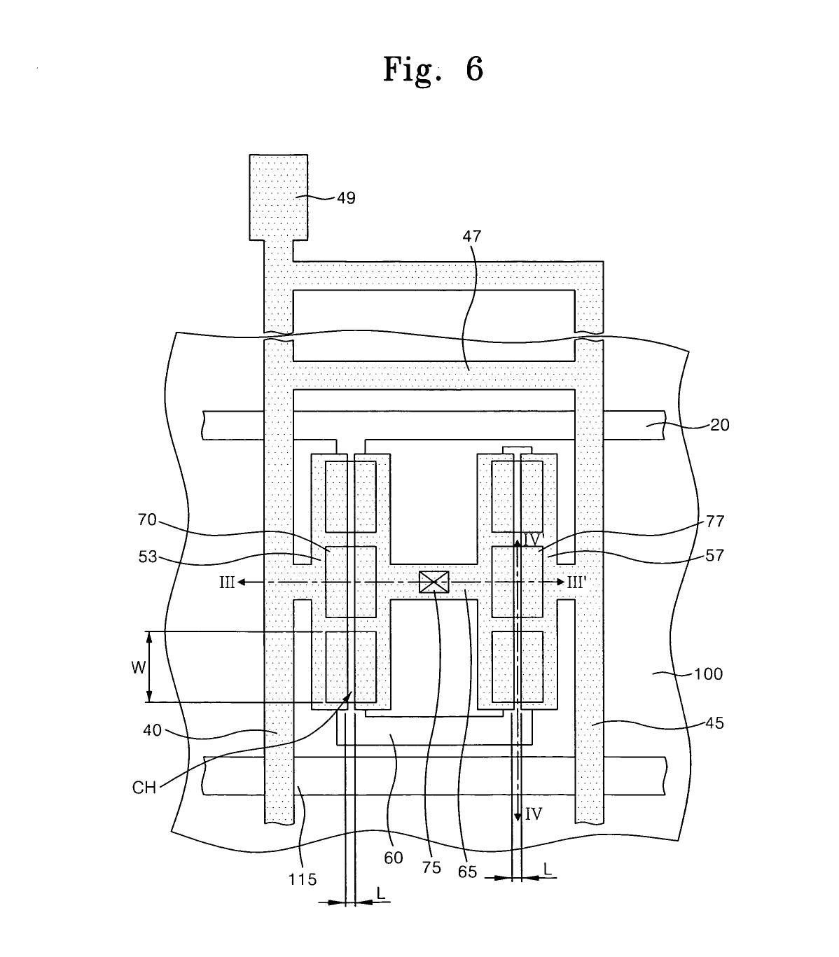

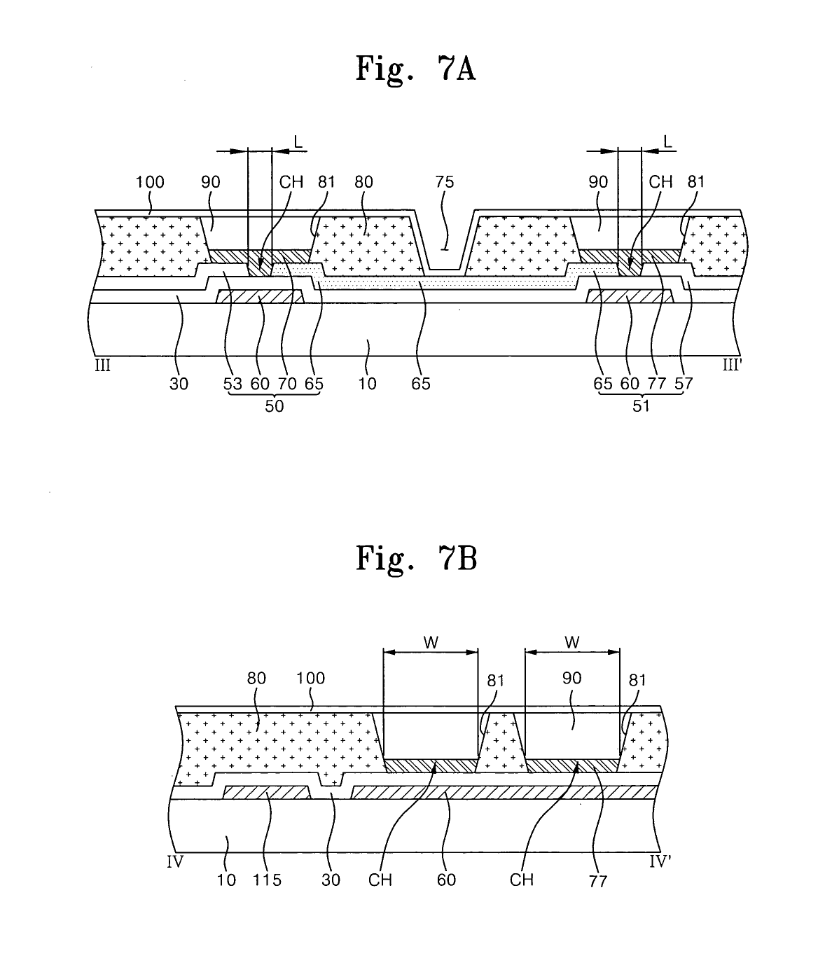

FIG. 6 is a partial top plan view of a fourth exemplary embodiment of an organic TFT substrate for a display device in accordance with the present invention, showing a single, exemplary pixel area thereof, FIG. 7A is a partial cross sectional view of the fourth exemplary substrate of FIG. 6, as seen along the lines of the section III-III′ taken therein, and FIG. 7B is a partial cross sectional view of the fourth exemplary substrate of FIG. 6, as seen along the lines of the section IV-IV′ taken therein.

Referring to FIGS. 6, 7A, and 7B, the fourth exemplary substrate includes six organic TFTs that are connected in parallel with one another. Hereinafter, an embodiment in which a first organic TFT 50 connected to the data line 40 and a second organic TFT 51 connected to the data line 40 will be described by way of example.

The fourth exemplary substrate includes a data pad 49, a gate line 20, a data line 40, an auxiliary data line 45, a connection line 47, a gate insulating layer 30, a storage pattern 117, first and second organic TFTs 50 and 51, a bank insulating layer 80, an organic passivation layer 90, and a pixel electrode 100.

The data pad 49 supplies the pixel voltage signal from a data driver (not illustrated) to the data line 40.

The gate line 20 crosses the data line 40, with the gate insulating layer 30 disposed therebetween. The gate line 20 and the data line 40 have the same structure as that of the third exemplary embodiment, and accordingly, further detailed description thereof is omitted.

The auxiliary data line 45 is connected to the data pad 49 and arranged so as to be parallel with the data line 40.

The connection line 47 is connected between the data line 40 and the auxiliary data line 45. The connection line 47 is substantially identical to the connection line of the third exemplary embodiment described above, and further detailed description thereof is therefore omitted.

The gate insulating layer 30, which is formed on the gate line 20, insulates the gate line 20 from the data line 40.

The storage pattern 115 that is parallel with the gate line 20 is formed of the same material as the gate line 20. A storage capacitor is formed by overlapping the pixel electrode 100 and the storage pattern 115 with the gate insulating layer 30 and the bank insulating layer 80 disposed therebetween.

The first and second organic TFTs 50 and 51 are connected in parallel with each other, and the width of their effective channel is thereby increased to improve the effective TFT on-current property. Each of the first and second organic TFTs 50 and 51 includes three sub-TFTs, and therefore, although any one of the sub-TFTs may break down due to bad ink jet print jetting, the pixel electrode 100 can still be turned on so as to implement normal pixel function. Each of the first and second organic TFTs 50 and 51 includes a main gate electrode 60, first and second source electrodes 53 and 57, a main drain electrode 65, and first and second organic semiconductor layers 70 and 77, respectively. The main gate electrode 60 is commonly connected to the first and second organic TFTs 50 and 51. More specifically, the main gate electrode 60 may be formed, for example, in the shape of the letter ‘U’, between the gate line 20 and the storage pattern 115 so as to commonly connect the first and second organic TFTs 50 and 51. Alternatively, the main gate electrode 60 may be formed in the shape of the character ‘∩’ or the letter ‘H’.

The first source electrode 53 is connected to the data line 40, and the second source electrode 57 is connected to the auxiliary data line 45. The first and second source electrodes 53 and 57 receive the pixel voltage signal through the data line 40 and auxiliary data line 45 commonly connected to the data pad 49.

The main drain electrode 65 is commonly connected to the first and second organic TFTs 50 and 51, and is connected to the pixel electrode 100 via the contact hole 75. The main gate electrode 65 may be formed, for example, in the shape of the letter ‘H’, and commonly connected to the first and second organic TFTs 50 and 51. The main drain electrode 65 supplies the pixel voltage signal from the first and second source electrodes 53 and 57 to the pixel electrode 100. The main gate electrode 65 may also be formed in the shape of the characters ‘∩’ or ‘□’ to the same effect.

The bank insulating layer 80 defines a hole that exposes a portion of the first and second source electrodes 53 and 57, and a portion of the main drain electrode 65.

The organic passivation layer 90, which is formed in the hole over the first and second organic semiconductor layers 70 and 77, serves to protect the first and second organic TFTs 50 and 51.

The pixel electrode 100 is connected to the main drain electrode 65 of the first and second organic TFTs 50 and 51 via the contact hole 75. The pixel electrode 100 implements a pixel using the pixel voltage signal supplied from the main drain electrode 65.

Although six organic TFTs are illustrated in the fourth exemplary embodiment, at least two organic TFTs may be sufficient, depending on the size of the pixel and the inkjet process used.

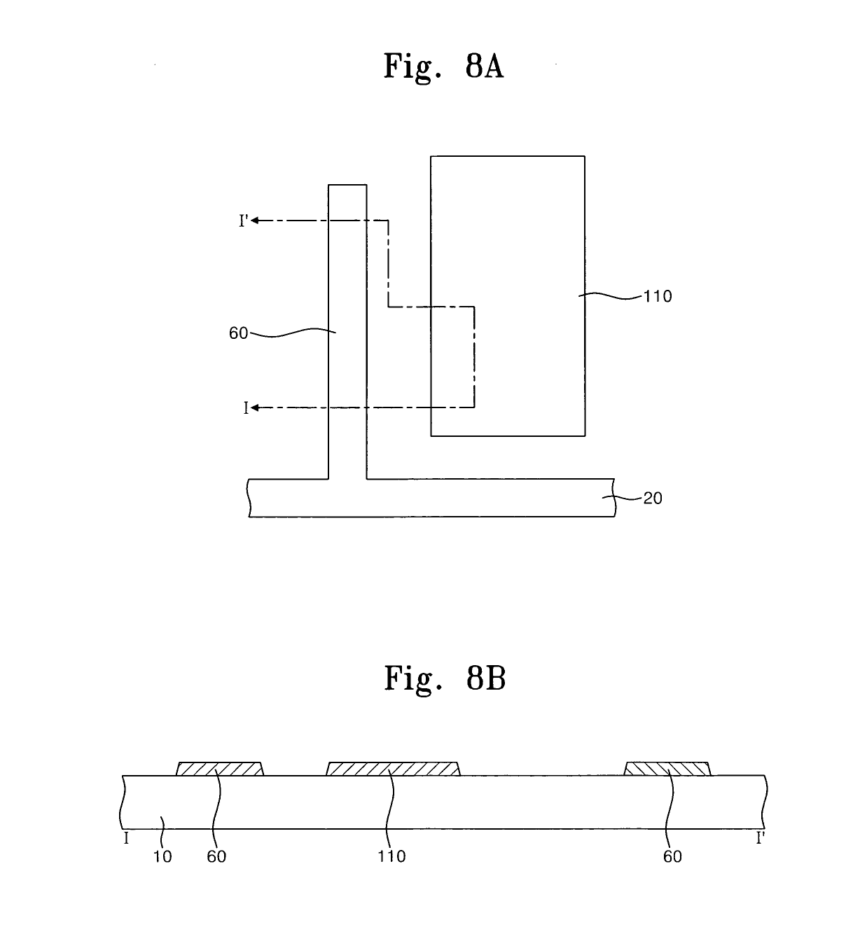

An exemplary embodiment of a method for manufacturing the first exemplary display substrate of FIG. 1 above is described in detail below with reference to FIGS. 8A to 13B.

FIG. 8A is a partial top plan view of the first exemplary substrate of FIG. 1, illustrating an exemplary embodiment of a method for forming the gate metal pattern thereof in accordance with the present invention, and FIG. 8B is a partial cross sectional view of the first exemplary substrate of FIG. 8A, as seen along the lines of the section I-I′ taken therein, and further illustrating the exemplary method for forming the gate metal pattern thereof.

Referring to FIGS. 8A and 8B, a gate line 20, a main gate electrode 60, and a storage lower electrode 110 are formed on an insulating substrate 10 that is formed of glass or plastic. A gate metal layer is formed on the substrate 10 by a deposition method, such as sputtering. The gate metal layer is formed in a single layer or multiple layer of a metal, which includes Mo, Nb, Cu, Al, Cr, Ag, W, or an alloy thereof. The gate metal layer is patterned by photolithography and etching processes using a mask to form a gate metal pattern, including the gate line 20, the main gate electrode 60, and the storage lower electrode 110.

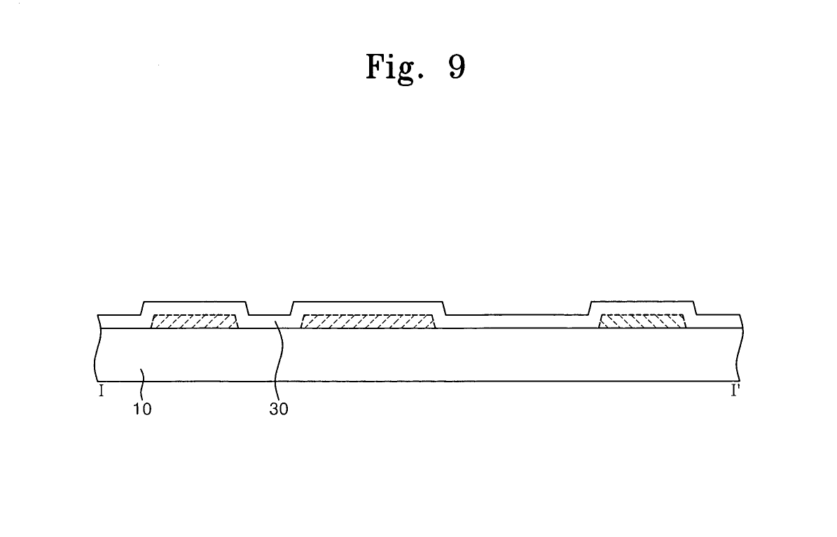

FIG. 9 is a partial cross sectional view of the first exemplary substrate of FIG. 8A, as seen along the lines of the section I-I′ taken therein, and illustrating an exemplary embodiment of a method for forming the gate insulating layer thereof in accordance with the present invention.

Referring to FIG. 9, the gate insulating layer 30 is formed on the substrate 10 including the gate metal pattern described above. The gate insulating layer 30 is formed by depositing an organic or an inorganic material on the entire surface of the gate metal pattern of the substrate 10. The gate insulating layer 30 may be formed, for example, by a plasma enhanced chemical vapor deposition (“PECVD”) process.

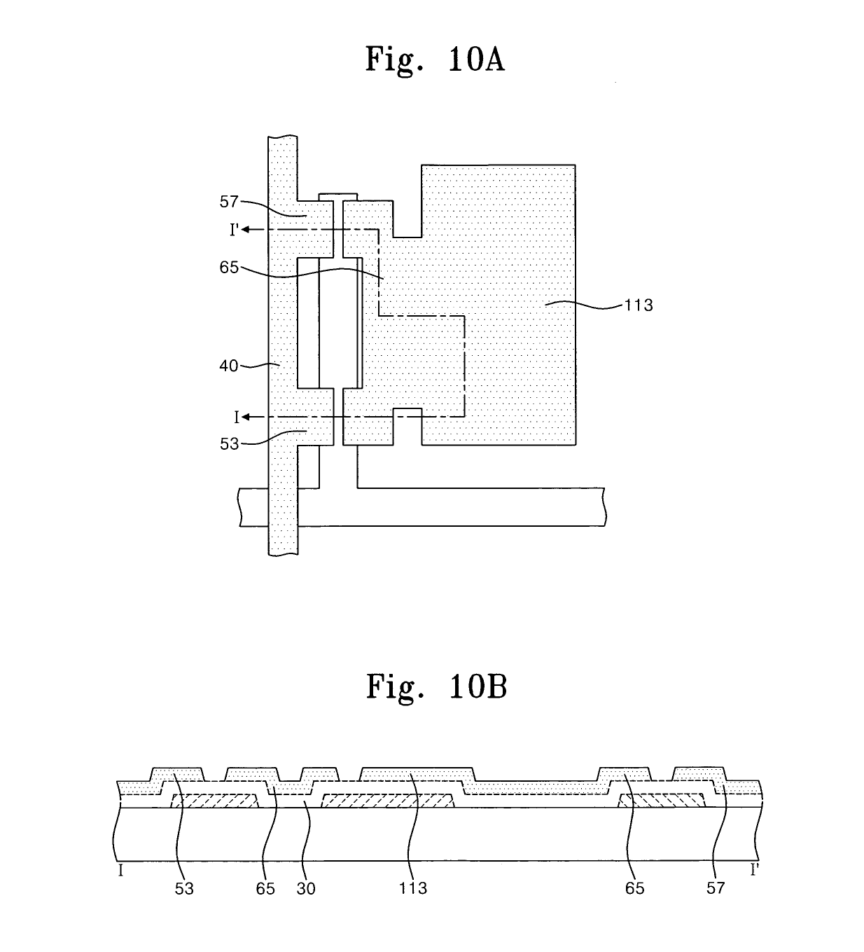

FIG. 10A is a partial top plan view of the first exemplary substrate of FIG. 1, illustrating an exemplary embodiment of a method for forming the data metal pattern thereof in accordance with the present invention, and FIG. 10B is a partial cross sectional view of the first exemplary substrate of FIG. 10A, as seen along the lines of the section I-I′ taken therein, and further illustrating the exemplary method for forming the data metal pattern thereof.

Referring to FIGS. 10A and 10B, a data line 40, first and second source electrodes 53 and 57, a main drain electrode 65, and a storage upper electrode 113 are formed on the gate insulating layer 30 described above. More specifically, a data metal layer is formed on the gate insulating layer 30 by a deposition method, such as sputtering. Subsequently, the data metal layer is patterned by photolithography and etching processes using a mask to form a data metal pattern including the data line 40, the first and second source electrodes 53 and 57, the main drain electrode 65, and the storage upper electrode 113.

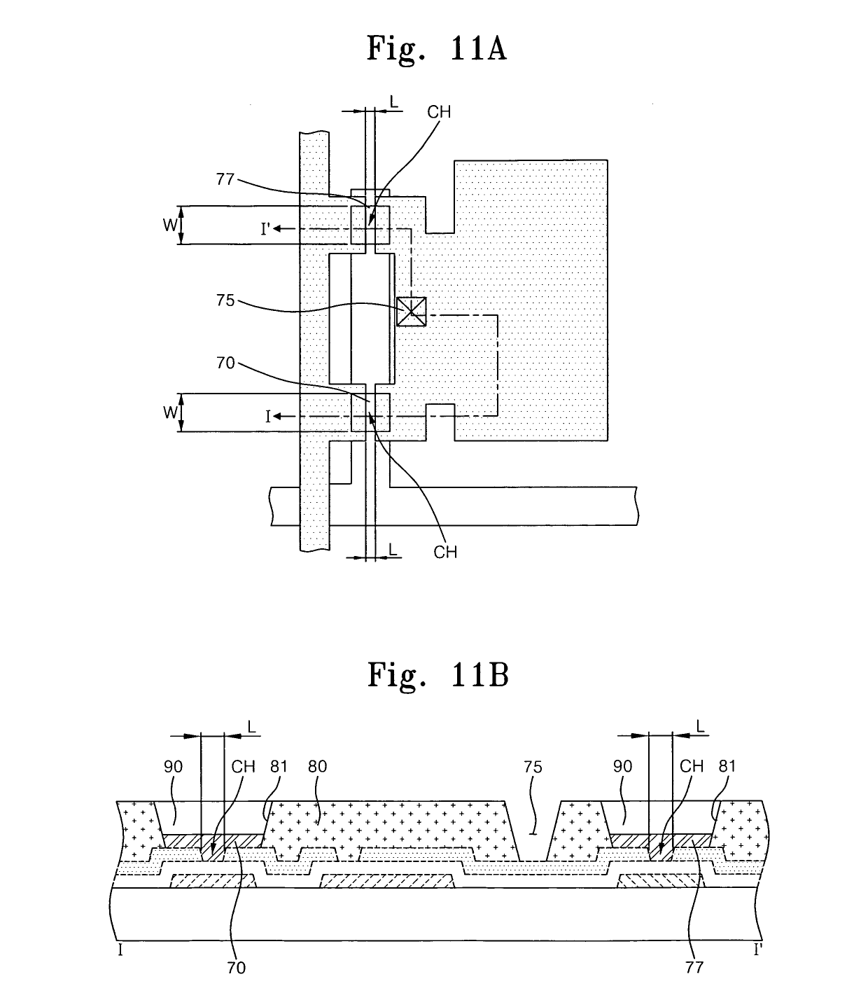

FIG. 11A is a partial top plan view of the first exemplary substrate of FIG. 1, showing the bank insulating layer, first and second organic semiconductor layers, and the passivation layer thereof, and FIG. 11B is a partial cross sectional view of the first exemplary substrate of FIG. 11A, as seen along the lines of the section I-I′ taken therein, and further illustrating the bank insulating layer, first and second organic semiconductor layers, and the passivation layer thereof.

Referring to FIGS. 11A and 11B, a contact hole 75, a bank insulating layer 80, first and second organic semiconductor layers 70 and 77, and an organic passivation layer 90 are formed on the data metal pattern described above. The first and second organic semiconductor layers 70 and 77 and the organic passivation layer 90 are formed in a hole defined by the bank insulating layer 80.

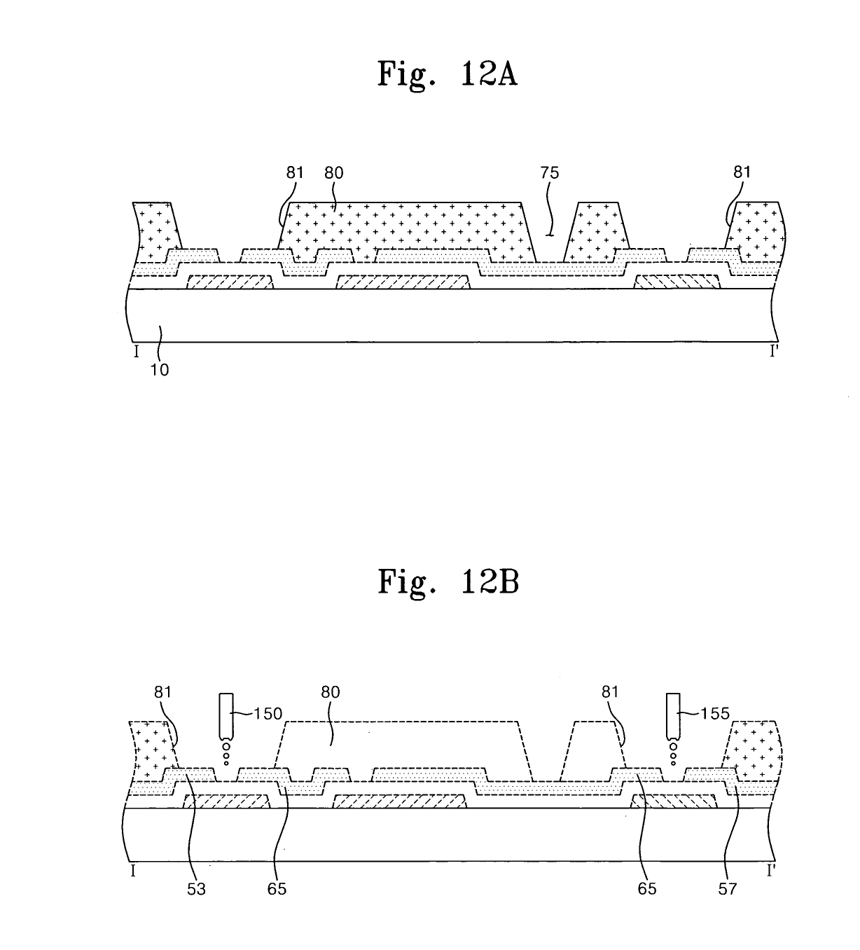

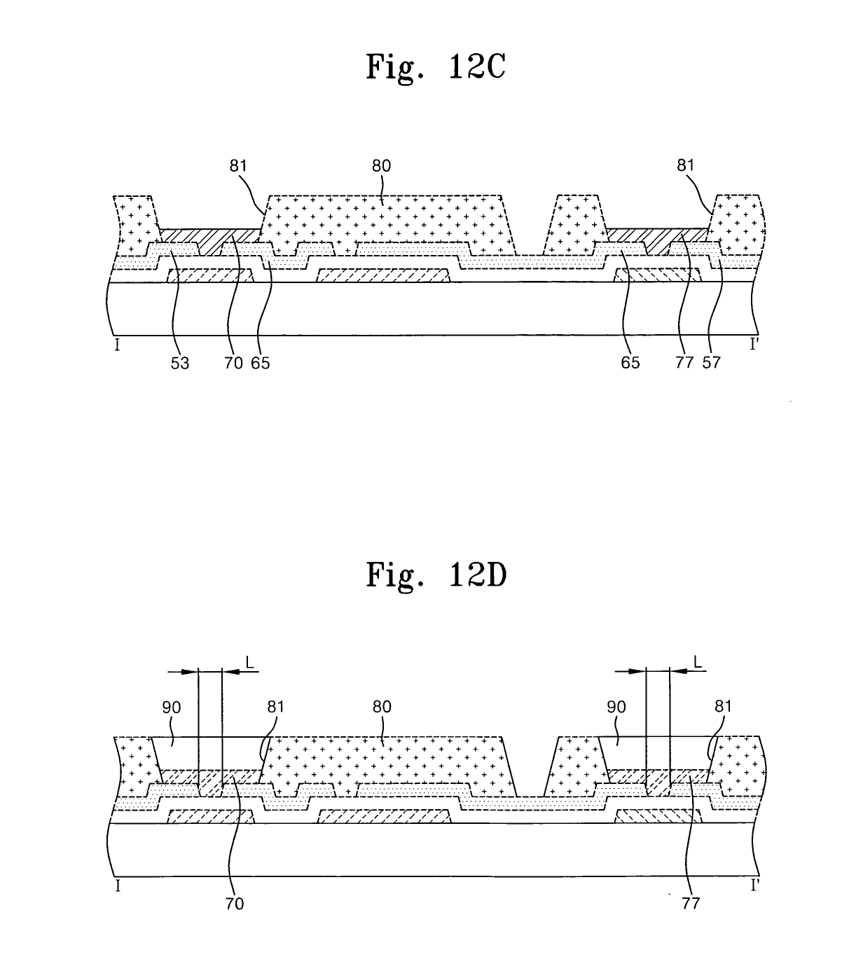

An exemplary embodiment of a method for forming the bank insulating layer, the first and second organic semiconductor layers, and the organic passivation layer is described in detail below with reference to FIGS. 12A, 12B, 12C, and 12D, wherein FIGS. 12A, 12B, 12C, and 12D are partial cross sectional views of the first exemplary substrate of FIG. 11A, as seen along the lines of the section I-I′ taken therein and illustrating sequential steps of the exemplary method for manufacturing the bank insulating layer, the first and second organic semiconductor layers, and the passivation layer illustrated in FIGS. 11A and 11B.

Referring to FIG. 12A, a bank insulating layer and a contact hole 75 are formed on the substrate including the data metal pattern described above. A photosensitive organic insulating material is deposited on the data metal pattern by a deposition method, such as the PECVD method. Next, the organic insulating material is patterned by photolithography and etching processes using a mask to form the bank insulating layer 80, which includes the hole and the contact hole. The bank insulating layer may be formed of a non-photosensitive organic insulating material.

Referring to FIG. 12B, the first and second organic semiconductor layers 70 and 77 are formed on the first and second source electrodes 53 and 57, and the main drain electrode 65, which are exposed by the hole. More specifically, as illustrated in FIG. 12B, a liquid organic semiconductor is injected in the hole using inkjet nozzles 150 and 155. Because two different nozzles 150 and 155 are used to form respective ones of the first and second organic semiconductor layers 70 and 77, in the event one of the nozzles does not work or operates unstably, thereby causing the breakdown of one of the first and second organic TFTs, the other TFT will continue to operate, and therefore, the associated pixel will operate normally. Although two nozzles are used in the exemplary embodiment, only a single nozzle may be used to spray the liquid organic semiconductor on the first and second organic semiconductor layers.

Next, the liquid organic semiconductor layer is cured to form the solid state first and second organic semiconductor layers 70 and 77, as illustrated in FIG. 12C. Subsequently, the first and second organic semiconductor layers 70 and 77 are subject to a SAM process, as described above. Accordingly, the first and second organic semiconductor layers 70 and 77 are ohmic-connected to the first and second source electrodes 53 and 57, and the main drain electrode 65, respectively.

Referring to FIG. 12D, an organic passivation layer 90 is formed in the hole including the first and second semiconductor layers 70 and 77. More specifically, the organic passivation layer 90 is formed by injecting a liquid insulating material, such as polyvinylacetate (“PVA”), in the hole with a nozzle and then curing it.

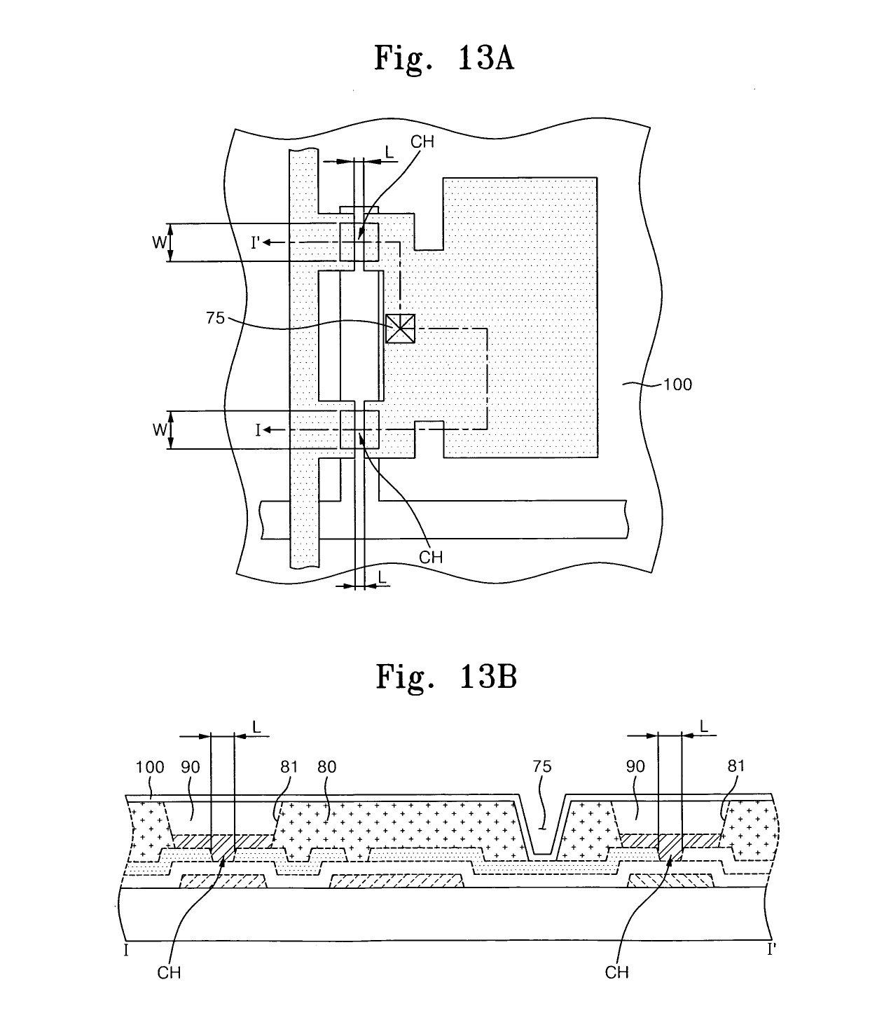

FIG. 13A is a partial top plan view of the first exemplary substrate of FIG. 1, illustrating an exemplary embodiment of a method for forming the pixel electrode thereof in accordance with the present invention, and FIG. 13B is a partial cross sectional view of the first exemplary substrate of FIG. 13B, as seen along lines of the section I-I′ taken therein, and further illustrating the exemplary method for forming the pixel electrode thereof.

Referring to FIGS. 13A and 13B, a pixel electrode 100 is formed on the contact hole 75, the bank insulating layer 80, and the organic passivation layer 90. More specifically, a transparent or reflective conductive material is formed by a deposition method, such as sputtering, on the contact hole 75, the bank insulating layer 80, and the organic passivation layer 90 described above. The transparent or reflective conductive material may include ITO, TO, IZO, or ITZO. Subsequently, the pixel electrode 100 is formed by photolithography and etching processes using a mask.

As described above, the exemplary embodiments of the present invention help to prevent the occurrence of bad pixels in a display, since at least two organic TFTs are provided in association with each pixel, and accordingly, even if one of the TFTs does not function properly, the other may be turned on normally so as to effect normal operation of the associated pixel.

Additionally, the exemplary embodiments of the present invention improve the on-current properties of the organic TFTs of a display since at least two organic TFTs are connected in parallel with each other. The exemplary embodiments of the present invention also serve to prevent the occurrence of line defects, since an auxiliary data line is further provided, through which the pixel voltage signal may be supplied even when a given data line does not work, and as a result, a degradation in display quality is prevented.

Although the present invention has been described with reference to certain exemplary embodiments thereof, it will be understood by those of skill in this art that a variety of modifications and variations may be made to the present invention without departing from the spirit and scope of the present invention as defined in the appended claims and their functional equivalents.

What is claimed is:

1. An organic thin film transistor substrate for a display device, comprising:
a gate line;
a data line insulated from the gate line;
at least two organic thin film transistors, each of which is connected between the gate line and the data line, the organic thin film transistors being commonly connected to a main drain electrode; and,
a pixel electrode connected to the main drain electrode.

2. The organic thin film transistor substrate of claim 1, wherein the organic thin film transistors are connected in parallel with one another.

3. The organic thin film transistor substrate of claim 2, further comprising:
a storage pattern, comprising
a storage lower electrode formed in the same plane as the gate line, and
a storage upper electrode formed in the same plane as the data line.

4. The organic thin film transistor substrate of claim 3, wherein the storage upper electrode is connected to the main drain electrode.

5. The organic thin film transistor substrate of claim 1, further comprising an auxiliary data line formed in the same plane as the data line and connected to any one of the organic thin film transistors.

6. The organic thin film transistor substrate of claim 5, further comprising a data pad connected to the data line and the auxiliary data line.

7. The organic thin film transistor substrate of claim 6, further comprising a connection line formed between the data line and the auxiliary data line.

8. The organic thin film transistor substrate of claim 5, wherein any one of the organic thin film transistors comprises,
a first gate electrode connected to the gate line,
a first source electrode connected to the data line, and
a first organic semiconductor layer connected to the first source electrode and the main drain electrode.

9. The organic thin film transistor substrate of claim 8, wherein another one of the organic thin film transistors comprises,
a second gate electrode connected to the gate line,
a second source electrode connected to the auxiliary data line, and
a second organic semiconductor layer connected to the second source electrode and the main drain electrode.

10. The organic thin film transistor substrate of claim 9, further comprising a bank insulating layer having a hole exposing the first and second source electrodes and the main drain electrode.

11. The organic thin film transistor substrate of claim 10, wherein the first gate electrode and the second gate electrode are connected in parallel with each other.

12. The organic thin film transistor substrate of claim 7, further comprising a storage pattern formed in the same plane as the gate line.

13. The organic thin film transistor substrate of claim 7, further comprising:
a storage pattern, comprising
a storage lower electrode formed in the same plane as the gate line, and
a storage upper electrode formed in the same plane as the data line.

14. A method for manufacturing an organic thin film transistor for a display device, the method comprising:
forming a gate metal pattern on a substrate, the gate metal pattern including a gate line and a gate electrode;
forming a gate insulating layer on the substrate and the gate metal pattern;
forming a data metal pattern on the gate insulating layer, the data metal pattern including a data line, at least two source electrodes and a main drain electrode; and,
respectively forming at least two organic semiconductor layers between the source electrodes and the main drain electrode.

15. The method of claim 14, wherein forming the data metal pattern comprises forming a connection line and an auxiliary data line on the gate insulating layer, the connection line and the auxiliary data line being connected to the data line.

16. The method of claim 14, wherein forming the gate metal pattern comprises forming a storage pattern on the substrate such that the storage pattern is parallel with the gate line.

17. The method of claim 14, wherein:
forming the gate metal pattern comprises forming a storage lower electrode on the substrate; and,
forming the data metal pattern comprises forming a storage upper electrode on the gate insulating layer.

18. The method of claim 14, further comprising forming a bank insulating layer on the data line, the two source electrodes, and the main drain electrode, the bank insulating layer including holes to expose the main drain electrode and the two source electrodes.

19. The method of claim 18, the bank insulating layer is formed of a photosensitive organic insulating material or a non-photosensitive organic insulating material.
